(19) United States
(12) Patent Application Publication
(10) Pub. No.: US 2012/0309117 A1
(43) Pub. Date: Dec. 6, 2012

(54) METHOD FOR MANUFACTURING SEMICONDUCTOR DEVICE

(75) Inventors: Yuichiro SUZUKI, Tokyo (JP); Atsushi Narazaki, Tokyo (JP); Yoshiaki Terasaki, Tokyo (JP)

(73) Assignee: MITSUBISHI ELECTRIC CORPORATION, Chiyoda-ku (JP)

(21) Appl. No.: 13/358,868

(22) Filed: Jan. 26, 2012

(30) Foreign Application Priority Data
Jun. 1, 2011 (JP) 2011-123719

(51) Int. Cl. H01L 21/66

(52) U.S. Cl. 438/10; 257/E21.531; 257/E21.53

(57) ABSTRACT

A method for manufacturing a semiconductor device wherein a semiconductor element is sealed with mold resin, a MOS structure is on an upper side of the semiconductor chip, and a PN junction region is on a back side of the semiconductor chip, comprises: obtaining an in-plane distribution of impurity concentration of the PN junction region in the semiconductor chip before encapsulation so that an in-plane distribution of breakdown voltage and leakage current of the semiconductor chip become uniform after encapsulation; forming the PN junction region having the obtained in-plane distribution of impurity concentration on the back side of the semiconductor chip; and sealing the semiconductor chip with the resin after forming the PN junction region.

### BACKGROUND OF THE INVENTION

1. Field of the Invention

The present invention relates to a method for manufacturing a resin encapsulated semiconductor device wherein semiconductor chips are encapsulated by resins.

2. Background Art

Resin encapsulated semiconductor devices wherein semiconductor chips are encapsulated by resins are broadly used. In such semiconductor devices, a difference in coefficients of thermal expansion between the resin and the semiconductor chip causes thermal stress. Also, currents concentrate in the junction surface between the wire or the lead frame and the semiconductor chip, and generate heat. Therefore, a problem is caused wherein the stress distribution and temperature distribution of the semiconductor chip after encapsulation become uneven, and the in-plane distribution of electrical characteristics of the semiconductor chip after encapsulation become dispersed. In recent years, with ultra thinning the thickness of the semiconductor chip to 200 μm or thinner, or raising the current density to 100 A/cm² or higher for high performance and low costs, the above-described problems are especially remarkable.

To solve such problems, a method has been proposed wherein the in-plane distribution of electrical characteristics of the semiconductor chip in the ON state is evened out by varying the distribution of impurity concentrations on the basis of distribution of stress applied to the semiconductor chip after encapsulation (for example, refer to Japanese Patent Application Laid-Open No. 2-14575).

### SUMMARY OF THE INVENTION

However, according to the conventional art, the in-plane distribution of breakdown voltage and leakage current, which are electric properties of semiconductor chips after encapsulation in the OFF state, could not be even. Therefore, there was the problem of the lowering of reliability.

In view of the above-described problems, an object of the present invention is to provide a method for manufacturing a semiconductor device which can make the in-plane distribution of the breakdown voltage and the leakage current of the semiconductor chip 1 after encapsulation to be uniform.

According to the present invention, a method for manufacturing a semiconductor device wherein a semiconductor element is sealed with mold resin, a MOS structure is on an upper side of the semiconductor chip, and a PN junction region is on a back side of the semiconductor chip, comprises: obtaining an in-plane distribution of impurity concentration of the PN junction region in the semiconductor chip before encapsulation so that an in-plane distribution of breakdown voltage and leakage current of the semiconductor chip become uniform after encapsulation; forming the PN junction region having the obtained in-plane distribution of impurity concentration on the back side of the semiconductor chip; and sealing the semiconductor chip with the resin after forming the PN junction region.

The present invention makes it possible to make the in-plane distribution of the breakdown voltage and the leakage current of the semiconductor chip 1 after encapsulation to be uniform.

Other and further objects, features and advantages of the invention will appear more fully from the following description.

### BRIEF DESCRIPTION OF THE DRAWINGS

FIG. 1 is a sectional view showing a semiconductor device according to an embodiment of the present invention.

FIGS. 2 to 8 are sectional views showing the fabricating steps of the semiconductor chip according to an embodiment of the present invention.

FIG. 9 is a flow chart showing the method for obtaining the in-plane distribution of the impurity concentration of the PN junction region.

FIG. 10 shows the method for obtaining the correlation of the in-plane distribution of the breakdown voltage and leakage current, and the stress distribution or the temperature distribution of the semiconductor chip.

FIG. 11 is a plan view of a semiconductor chip before encapsulation viewed from the back side.

FIG. 12 is a graph showing the obtained result of stress applied to I to II in FIG. 11.

FIG. 13 is a graph showing the relations of “the breakdown voltage and the leakage current with the N-type impurity concentration of the N+-type buffer region”, “the P-type impurity concentration of the P+-type collector region”, and “the temperature of the semiconductor chip”.

FIG. 14 is a plan view from the back side of the semiconductor chip wherein the in-plane distribution of the N-type impurity concentration of the N+-type buffer region before encapsulation is such that the in-plane distribution of breakdown voltage and leakage current after encapsulation becomes uniform.

### DETAILED DESCRIPTION OF THE PREFERRED EMBODIMENTS

A method for manufacturing a semiconductor device according to the embodiments of the present invention will be described with reference to the drawings. The same components will be denoted by the same symbols, and the repeated description thereof may be omitted.

### First Embodiment

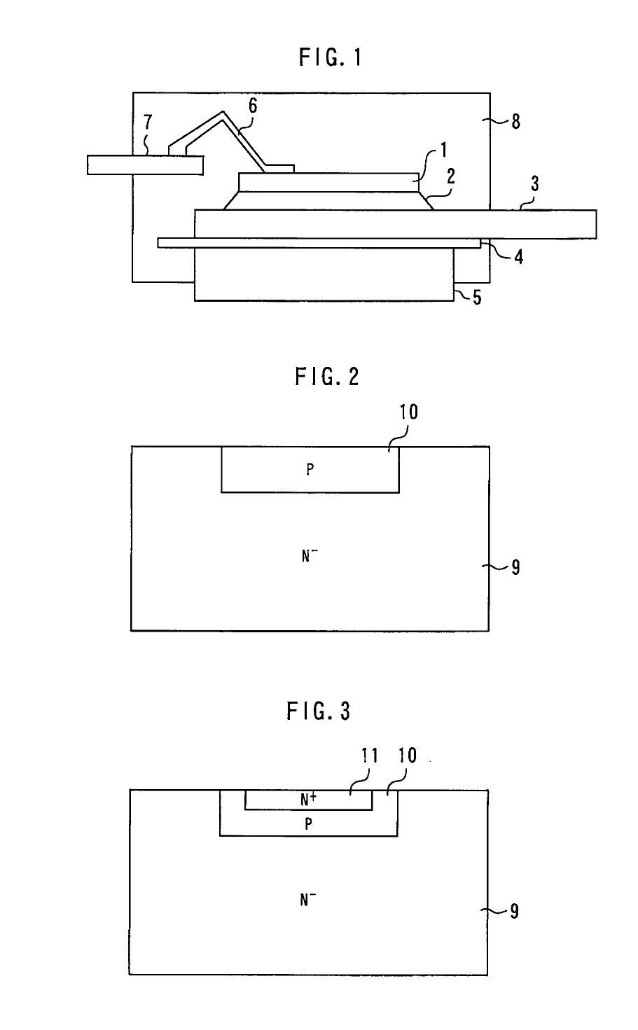

FIG. 1 is a sectional view showing a semiconductor device according to an embodiment of the present invention. The back side of the semiconductor chip 1 is joined to the electrode substrate 3 by the electrically-conductive junction material 2. The electrically-conductive junction material 2 is solder, Ag paste, or an electrically-conductive adhesive. The electrode substrate 3 is mounted on a heatsink 5 via an insulating sheet 4 having an excellent thermal conductivity. The surface of the semiconductor chip 1 is connected to an external wiring terminal 7 by an Al or Cu wire 6. The semiconductor chip 1, a part of the electrode substrate 3, the insulating sheet 4, a part of the heatsink 5, the wire 6, and a part of the external wiring terminal 7 are sealed by an insulating resin 8.

Subsequently, the fabricating steps of the semiconductor chip 1 will be described referring to the drawings. FIGS. 2 to 8 are sectional views showing the fabricating steps of the semiconductor chip according to an embodiment of the present invention. Here, the semiconductor chip 1 is an IGBT (Insulated Gate Bipolar Transistor). However, the semiconductor chip 1 is not limited to an IGBT, but can be an MOSFET (Metal-Oxide-Semiconductor Field-Effect Transistor) or a diode.

First, as shown in FIG. 2, P-type impurity ions are implanted and diffused into the surface side of the N⁻-type semiconductor substrate 9 to form a P-type base region 10. The N⁻-type semiconductor substrate 9 is formed of Si, GaAs, GaN, SiC or the like. Next, as shown in FIG. 3, N-type impurity ions are implanted and diffused into a part of the P-type base region 10 to form an N⁺-type source region 11.

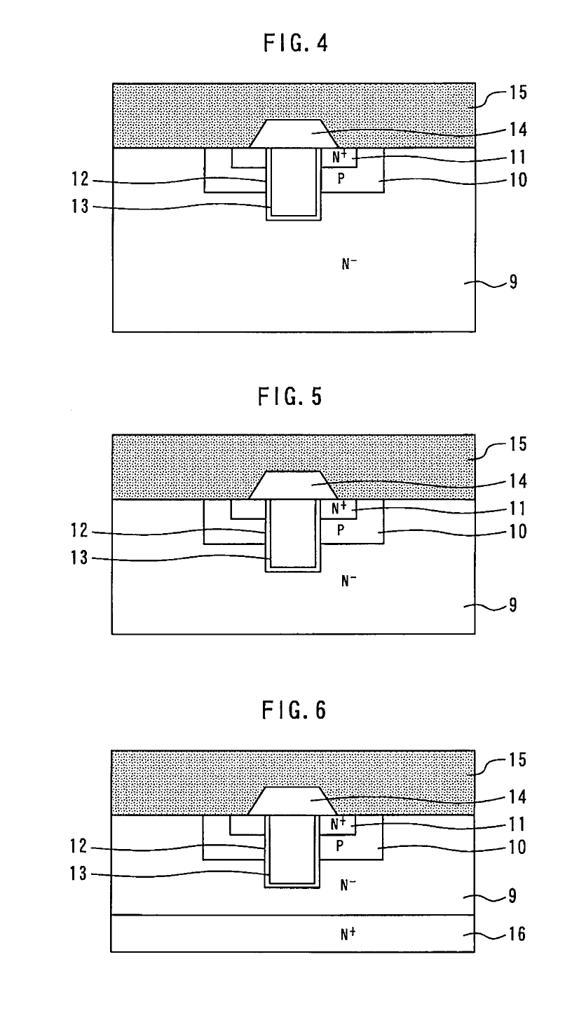

Next, as shown in FIG. 4, a trench passing through the N⁴-type source region 11 and the P-type base region 10 is formed, and a gate electrode 13 is buried in the trench via a gate insulation film 12. An interlayer insulation film 14 is formed on the gate electrode 13 to form an emitter electrode 15 over the entire surface.

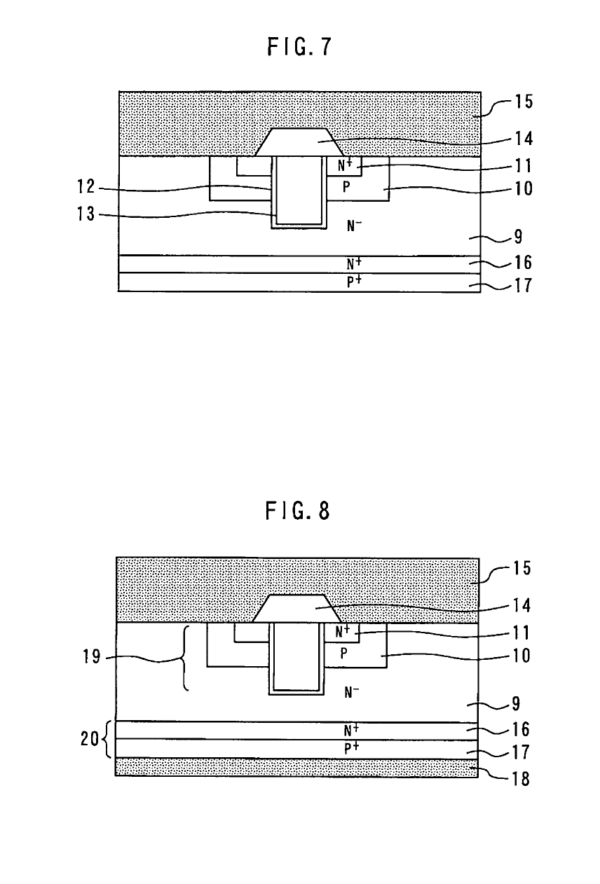

Then, as shown in FIG. 5, the N⁻-type semiconductor substrate 9 is ground from the back side to a predetermined thickness. Next, as shown in FIG. 6, N-type impurity ions are implanted and diffused into the entire back face of the N⁻-type semiconductor substrate 9 to form an N⁺-type buffer region 16. Then, as shown in FIG. 7, P-type impurity ions are implanted and diffused into the entire back face of the N⁻-type semiconductor substrate 9 to form a P⁺-type collector region 17.

Lastly, as shown in FIG. 8, a collector electrode 18 is formed on the entire back face of the N⁻-type semiconductor substrate 9. By the above described steps, the semiconductor chip 1 is fabricated. Here, a MOS structure 19 is set on the upper side of the semiconductor chip 1, and the PN junction region is set on the back side of the semiconductor chip 1.

Subsequently, the method for fabricating the semiconductor device according to the embodiments of the present invention will be described. Firstly, before encapsulating the semiconductor chip 1 using a resin 8, the in-plane distribution of the impurity concentration of the PN junction region (N⁺-type buffer region 16 and P⁺-type collector region 17) in the semiconductor chip 1 before encapsulation is obtained so that the in-plane distribution of the breakdown voltage and the leakage current of the semiconductor chip 1 become uniform after encapsulation.

Subsequently, a PN junction region 20 having the obtained in-plane distribution of impurity concentration is formed on the bake side of the semiconductor chip 1. Thereafter, the semiconductor chip 1 is connected to the external wiring terminal 7 by the wire 6, and the semiconductor chip 1 is sealed with the resin 8.

In addition, as the method for forming impurity concentration distribution, for example, there is a method wherein the scanning speed of the ion implanting device is varied. Thereby, impurity concentration distribution can be formed only by changing the process conditions of the ion implanting device without adding new processes. Alternatively, impurity ions can be implanted into the semiconductor substrate using a photoresist mask or a stencil mask corresponding to the impurity concentration distribution. In this case, since an existing photoengraving process is used, a minute impurity concentration distribution can be formed.

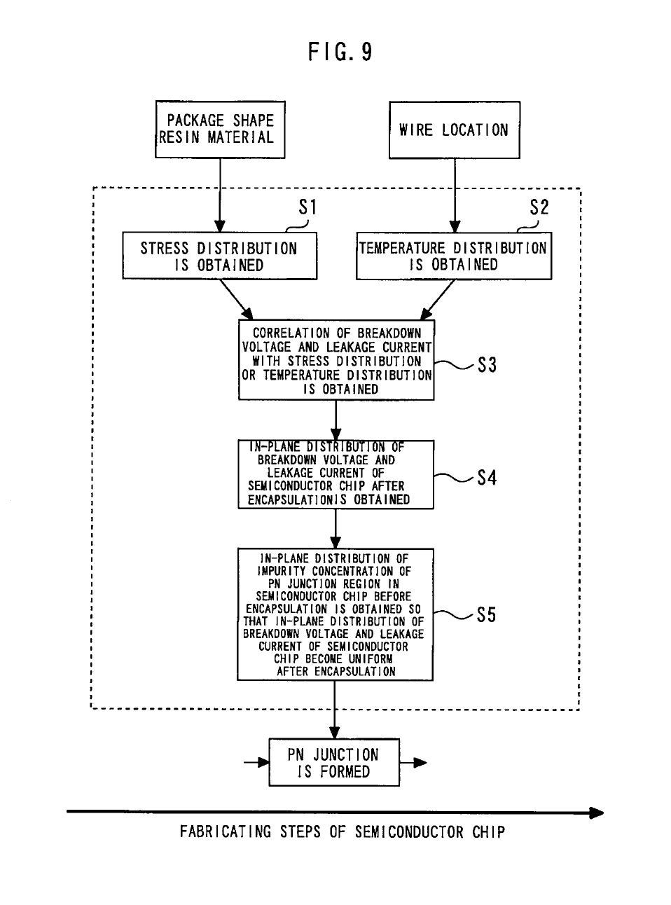

Subsequently, the method for obtaining the in-plane distribution of the impurity concentration of the PN junction region will be described in detail referring to the flow chart in FIG. 9.

Firstly, the stress distribution added to the semiconductor chip 1 after encapsulation on the basis of the shape of the package and the material of the resin 8 is obtained (Step S1). For example, the stress distribution is obtained by simulation using an FEM analysis. Alternatively, a stress measuring element, such as a piezo element or a strain gauge, is arranged in the plane of the semiconductor chip 1 to measure stress distribution.

Then, the density distribution of the current flowing in the semiconductor chip 1 after encapsulation is obtained on the basis of the location of the wire 6, and the temperature distribution of the semiconductor chip 1 after encapsulation is obtained from the density distribution of the current (Step S2). For example, the temperature distribution of the semiconductor chip 1 is obtained by simulation. Alternatively, the temperature distribution of the semiconductor chip 1 is measured using a thereto-viewer or the like.

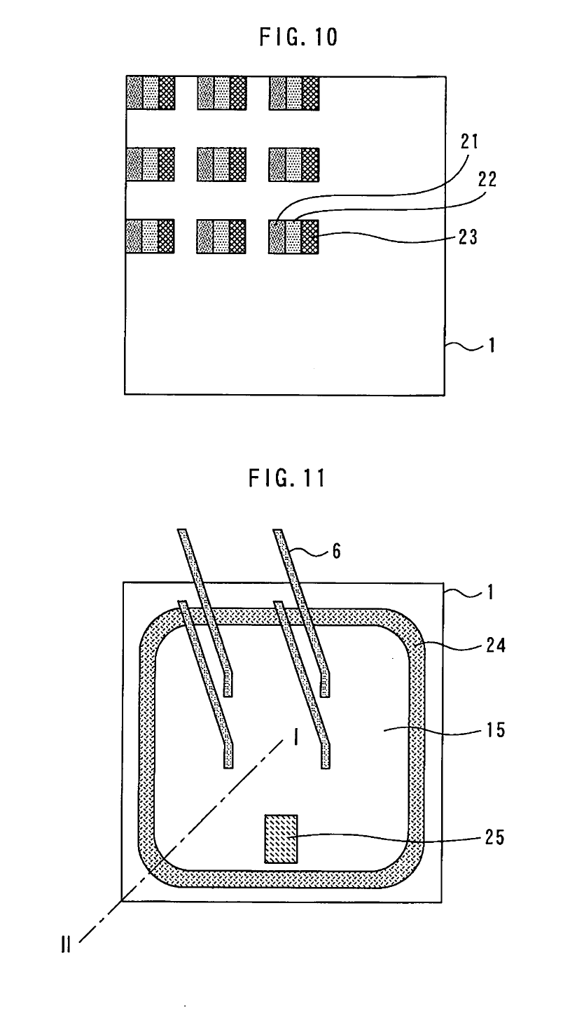

Subsequently, the correlation of the breakdown voltage and in-plane distribution with the stress distribution or with the temperature distribution of the semiconductor chip 1 is obtained (Step S3). For example, as shown in FIG. 10, stress measurement elements 21 such as piezo elements, temperature measurement elements 22, and semiconductor elements 23 that are far smaller than the semiconductor chip 1 are placed in respective regions on the surface of the semiconductor chip 1. Then, stress is measured using the stress measurement element 21 in the state wherein stress is applied to the semiconductor chip 1, the temperature is measured using the temperature measurement element 22, and at the same time, the breakdown voltage and leakage current of the semiconductor elements 23 are measured. Thereby, the correlation of the in-plane distribution of the breakdown voltage and leakage current, and the stress distribution or the temperature distribution of the semiconductor chip 1 can be obtained. The temperature of the semiconductor chip 1 can also be measured using a thermocouple or a thermo-viewer in place of using the temperature measurement element 22.

Subsequently, from the correlation of the breakdown voltage and leakage current with the stress distribution or the temperature distribution of the semiconductor chip 1, the in-plane distribution of the breakdown voltage and leakage current of the semiconductor chip 1 after encapsulation are obtained (Step S4).

Finally, the in-plane distribution of the impurity concentration of the PN junction region 20 of the semiconductor chip 1 before encapsulation is obtained so that the in-plane distribution of the breakdown voltage and leakage current of the semiconductor chip 1 after encapsulation becomes uniform (Step S5).

FIG. 11 is a plan view of a semiconductor chip before encapsulation viewed from the back side. An emitter electrode 15 and a gate pad 25 are placed in an end region 24. Wires 6 are joined to the emitter electrode 15.

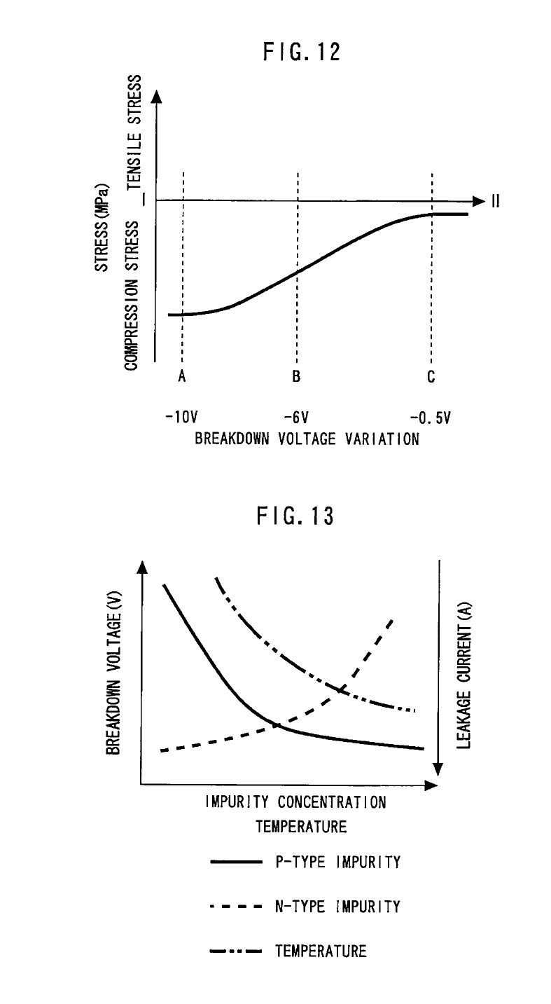

FIG. 12 is a graph showing the obtained result of stress applied to I to II in FIG. 11. In FIG. 12, the variation of the breakdown voltage when the stresses A, B, and C applied to the semiconductor chip 1 is also shown. After encapsulation, a large compression stress is applied to the central portion I of the semiconductor chip 1 compared with the stress to the corner portion II, and the fluctuation range of the breakdown voltage is also increased in parallel to the stress. Furthermore, since currents from surrounding regions are collected to the region where the wire 6 of the semiconductor chip 1 is connected when the transistor is operated, temperature rises more than the surrounding regions.

FIG. 13 is a graph showing the relations of “the breakdown voltage and the leakage current with the N-type impurity concentration of the N⁺-type buffer region 16”, “the P-type impurity concentration of the P⁺-type collector region 17”, and “the temperature of the semiconductor chip 1”. As the impurity concentration lowers, or the temperature elevates, the breakdown voltage is lowered, and the leakage current is elevated.

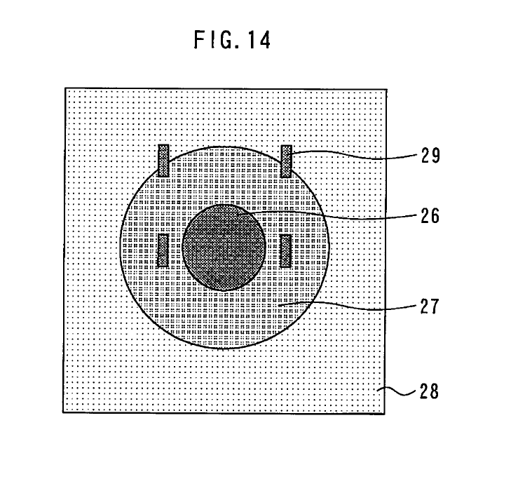

FIG. 14 is a plan view from the back side of the semiconductor chip 1 wherein the in-plane distribution of the N-type impurity concentration of the N+-type buffer region 16 before encapsulation is such that the in-plane distribution of breakdown voltage and leakage current after encapsulation becomes uniform. The center region 26 has a high impurity concentration. The impurity concentration in the region 27 is lower than the impurity concentration in the region 26, and the impurity concentration in the region 28 is further lower than the impurity concentration in the region 27. The region 29 is a region where the wire 6 is joined, and has a high impurity concentration. Although the N⁺-type buffer region 16 is described here, the same can be said of the P⁺-type collector region 17.

When stress is applied to the N⁻-type semiconductor substrate 9 of the semiconductor chip 1, the breakdown voltage is lowered, and the leakage current is elevated. Therefore, the impurity concentration of the N⁺-type buffer region 16 in the region 26 where stress is applied after encapsulation is relatively elevated. Since the breakdown voltage of the region 26 before encapsulation is relatively elevated thereby, the in-plane distribution of the breakdown voltage and the leakage current of the semiconductor chip 1 after encapsulation become uniform.

In addition, in the region 29 where wires 6 are joined in the semiconductor chip 1, since currents are collected from the surrounding regions toward the wire 6 in the operation of the transistor, the temperature is elevated, the breakdown voltage is lowered, and the leakage current is elevated than the surrounding regions. Therefore, the impurity concentration in the N⁺-type buffer region 16 in the region 29 is relatively elevated. Thereby, even if a current is flowed in the wire 6 and the temperature is elevated, the in-plane distribution of the breakdown voltage and the leakage current of the semiconductor chip 1 after encapsulation become uniform.

As described above, in the present embodiment, the in-plane distribution of the impurity concentration in the PN junction region 20 of the semiconductor chip 1 before encapsulation, wherein the in-plane distribution of the breakdown voltage and the leakage current of the semiconductor chip 1 after encapsulation become uniform, is previously obtained. Then, the PN junction region 20 having the in-plane distribution of the obtained impurity concentration is formed on the back side of the semiconductor chip 1. Thereafter, the semiconductor chip 1 is sealed with the resin 8. Thereby, the in-plane distribution of the breakdown voltage and the leakage current of the semiconductor chip 1 after encapsulation can be made to be uniform. Therefore, the reliability of the semiconductor device can be improved.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-123719, filed on Jun. 1, 2011 including specification, claims, drawings and summary, on which the Convention priority of the present application is based, are incorporated herein by reference in its entirety.

What is claimed is:

1. A method for manufacturing a semiconductor device wherein a semiconductor element is sealed with mold resin, a MOS structure is on an upper side of the semiconductor chip, and a PN junction region is on a back side of the semiconductor chip, comprising:
obtaining an in-plane distribution of impurity concentration of the PN junction region in the semiconductor chip before encapsulation so that an in-plane distribution of breakdown voltage and leakage current of the semiconductor chip become uniform after encapsulation;
forming the PN junction region having the obtained in-plane distribution of impurity concentration on the back side of the semiconductor chip; and
sealing the semiconductor chip with the resin after forming the PN junction region.

2. The method for manufacturing a semiconductor device according to claim 1, wherein the step of obtaining the in-plane distribution of the impurity concentration of the PN junction region comprising:
obtaining a stress distribution of the semiconductor chip after encapsulation; and
obtaining an in-plane distribution of breakdown voltage and leakage current of the semiconductor chip after encapsulation from a correlation of breakdown voltage and leakage current with the stress distribution of the semiconductor chip.

3. The method for manufacturing a semiconductor device according to claim 1, wherein the step of obtaining the in-plane distribution of the impurity concentration of the PN junction region comprising:
obtaining a temperature distribution of the semiconductor chip after encapsulation from a density distribution of current flowing in the semiconductor chip after encapsulation; and
obtaining an in-plane distribution of breakdown voltage and leakage current of the semiconductor chip after encapsulation from a correlation of breakdown voltage and leakage current with the temperature distribution of the semiconductor chip.
